(19) United States
(12) Patent Application Publication
(10) Pub. No.: US 2004/0145060 A1
(43) Pub. Date: Jul. 29, 2004

(54) Laser marking passivation film for semiconductor package

(76) Inventor: Christopher J. Dominic, Cerritos, CA (US)

Correspondence Address: Jane E. Gennaro, Counsel, Intellectual Property, NATIONAL STARCH AND CHEMICAL COMPANY, 10 Finderne Avenue, Bridgewater, NJ, 08807-0500, US

(21) Appl. No.: 10/350,536

(22) Filed: Jan. 23, 2003

(51) Int. Cl. H01L 23/48; H01L 23/52; H01L 29/40

(52) U.S. Cl. 257/768

(57) ABSTRACT

An adhesive film having a light colored layer and a dark colored layer is applied to the non-active face of a silicon wafer to protect the wafer when it is singulated into individual dies. The protective film is thick enough to allow laser marking of the die, such that the light colored layer shows through the laser etching of the dark colored layer.

### FIELD OF THE INVENTION

This invention relates to a film that is applied to the non-active face of a silicon wafer to protect the wafer against chipping during and after singulation into individual dies and that can be marked with a laser.

### BACKGROUND OF THE INVENTION

In the fabrication of semiconductor devices, a silicon wafer at some point is singulated, by dicing or sawing, into individual dies. The dicing or sawing operation and subsequent mechanical handling can result in chipped edges. To provide mechanical support as a means to prevent chipped edges, manufacturers can add a protective coating to the wafer backside (the side not containing the active circuitry). An example of such a protective film is disclosed in U.S. Pat. No. 6,175,162 B1. The protective film is thick enough to give mechanical support, to allow laser marking of the die, and to provide protection from electrostatic shock, light induced bias. Laser marking is a preferred means to identify the dies, which ensures that the dies are distributed to the correct end user and circuit boards are populated correctly. Some machines used to populate boards read identification markings on the dies electronically, but conventional ink printing processes do not provide the resolution and legibility necessary for electronic reading, especially for small dies.

### SUMMARY OF THE INVENTION

This invention is an improvement on the film that can be applied to the backside of a silicon wafer, particularly those that will be singulated into flip-chip semiconductors, to provide mechanical support and protection from electrostatic shock or light induced bias, and to allow identification by laser marking. This invention comprises a two layer film, in which one layer is light colored and one layer is dark colored, or in which the layers are of contrasting colors, such as blue and orange, or green and yellow, and in which the layers are laminated together. These films also provide a uniform thickness compared to protection layers applied by printing techniques.

### DETAILED DESCRIPTION OF THE INVENTION

In practice, it will be preferred if the light layer (or the brighter color) is placed proximate to the silicon wafer and the dark layer is the layer etched by the laser. This results in light writing on a dark background and resembles currently used (white) printing on (gray) plastic molded packages. Another advantage is that the laser energy is absorbed more strongly by the dark layer than by the light layer, making it faster to cut through the dark layer and then halt at the light layer. As a result, the cut depth is to some extent self-regulating.

In order to impart color to the chosen resin, any inert colored filler that has a fine particle size, that is easily dispersible, non-abrasive and ionically clean, may be added to the resin. A preferred light colored filler is titanium dioxide because it has these attributes. A preferred dark filler is carbon black; it has the attributes of being very black, it burns easily by laser leaving no residue, is relatively inexpensive and available in a wide variety of grades. A preferred grade for this use is channel black.

Alternative color choices can also be used such as: off-white, yellow, blue, orange, green, red, brown, purple. The following table lists various colors and the generic chemical composition of the pigment to give those colors.

| | |
|---|---|
| Crimson | Anthraquinonoid, Dioxazine |
| Crimson | Anthraquinone |
| Crimson | Anthraquinone |
| Crimson | 1:2 Dihydroxyanthraquinone Lake |
| Crimson | Quinacridone Pyrrolidone |
| Crimson | Quinacridone Pyrrolidone, Quinacridone |
| Black | Specified Carbon Black |
| Black | Carbon Black |
| Blue | Copper Phthalocyanine |
| Blue | Phthalocyanine Blue |
| Blue | Ultramarine Blue |
| Blue | Ultramarine Blue |
| Blue | Ultramarine Blue |
| Blue | Ultramarine Blue |
| Ultramarine Blue | Complex Silicate of Sodium and Aluminum with |
| | Sulfur |
| Ultramarine Blue | Complex Silicate of Sodium and Aluminum with |
| | Sulfur |
| Deep Blue | Phthalocyanine Complex |
| Deep Blue | Complex of Sodium -Aluminum- Silica containing |
| | Sulphur, Phthalocyanine Alpha |
| Light Blue | Phthalocyanine, Titanium [Dioxide] |
| Light Blue | Titanium Dioxide, Chlorinated Phthalocyanine, |
| | Phthalocyanine Beta |
| Light Blue | Zinc Oxide, Phthalocyanine Beta |
| Blue Violet | Dioxazine, Quinacridone |
| Blue Violet | Dioxazine, Quinacridone |
| Blue Violet | Dioxazine, Quinacridone |
| Bright Green | Arylide Yellow 10G, Chlorinated Copper |
| | Phthalocyanine, Zinc Oxide |
| Bright Green | Arylide Yellow 10G, Chlorinated Copper |
| | Phthalocyanine, Zinc Oxide |
| Brown | Monoazo Complex |
| Brown | Benzimidazolone |
| Carmine | Napthol Carbamide |
| Carmine | Naphthol ITR |
| Carmine | Quinacridone Red |
| Carmine | Quinacridone Pyrrolidone |
| Chinese White | Zinc Oxide |
| Cyan | Phthalocyanine Blue |
| Dark Yellow | Arylide Yellow RN |
| Geranium | Quinacridone, Anthraquinone |
| Geranium | Chlorinated Para Red, Quinacridone |
| Green | Phthalocyanine Green, Diarylide Yellow |
| Green | Phthalo Green, Arylide Yellow 10G |
| Green | Phthalo Green, Zinc White |
| Green | Phthalocyanine Green |
| Green | Phthalo Green, Monoazo Yellow |
| Green | Phthalo Green, Monoazo Yellow |
| Green | Cadmium Sulfide, Cobalt Oxide |
| Green | Zinc Oxide, Titanium Dioxide Rutile, Stable |
| | Monoazo, Phthalocyanine |
| Green | Arylamide Yellow, Synthetic Iron Oxide, |
| | Chlorinated Copper Phthalocyanine |
| Green | Hydrated Chromium Oxide, Cadmium Sulfide |
| Green | Hansa Yellow 10G, Phthalocyanine Beta |
| Green | Disazo Pigment, Copper Phthalocyanine, Nickel- |
| | Antimony Titanate |
| Green | Benzimidazolone, Phthalocyanine Green |
| Green | Polychloro Copper Phthalocyanine, Nickel- |
| | Antimony Titanate, Monoazo Pigment |
| Green | Nickel-Antimony Titanate, Disazo Pigment, |
| | Polychloro Copper Phthalocyanine |
| Green | Nickel-Antimony Titanate, Monoazo Pigment, |
| | Copper Phthalocyanine |
| Deep Green | Nickeltitanium, Phthalocyanine |
| Deep Green | Phthalocyanine Green, Arylide Yellow FGL, |
| | Titanium Dioxide |
| Deep Green | Chlorinated Phthalocyanine, Arylide Yellow, |
| | Titanium Dioxide |
| Deep Green | Chlorinated Copper Phthalocyanine, Arylamide |
| | Yellow |
| Deep Green | Polychloro Copper Phthalocyanine |
| Deep Green | Phthalocyanine with Extender |
| Deep Green | Trisulfonated Copper Phthalocyanine Lake, |
| | Monoazo Pigment, Polychloro Copper |
| | Phthalocyanine |
| Deep Green | Zinc Sulfide/Barium Sulfate, Monoazo Yellow, |
| | Phthalocyanine Blue, Metal Complex |
| Deep Green | Chlorinated Copper Phthalocyanine, Arylamide |
| | Yellow |
| Deep Green | Zinc Sulfide/Barium Sulfate, Monoazo Yellow, |
| | Phthalocyanine Green |
| Deep Green | Arylide Yellow, Chlorinated Copper |
| | Phthalocyanine |
| Deep Green | Disazo Pigment, Copper Phthalocyanine |
| Deep Green | Zinc Oxide, Titanium Dioxide Rutile, Synthetic |
| | Ultramarine B29, Phthalocyanine, Stable Di- |
| | Arylide |
| Deep Green | Hydrated Chromium Oxide, Phthalocyanine Green |
| Deep Green | Chlorinated Copper Phthalocyanine, Arylamide |
| | Yellow |
| Deep Green | Chlorinated Phthalocyanine, Complex of Sodium - |
| | Aluminum- Silica containing Sulphur, Cadmium |
| | Sulfide |
| Deep Green | Chlorinated Phthalocyanine, Phthalocyanine |
| | Alpha, Hansa Yellow 10G |
| Deep Green | Complex of Sodium -Aluminum- Silica containing |
| | Sulphur, Chlorinated Phthalocyanine |
| Deep Green | Hydrated Chrome Oxide |
| Deep Green | Arylide, Copperphthalocyanine |
| Deep Green | Arylide, Copperphthalocyanine |
| Light Green | Phthalocyanine, Arylamide |
| Light Green | Arylide Yellow, Chlorinated Copper |
| | Phthalocyanine |
| Light Green | Concentrated Cadmium Zinc Sulfide, Chlorinated |
| | Copper Phthalocyanine |
| Light Green | Phthalocyanine, Titanium [Dioxide] |
| Light Green | Cadmium Sulfide, Chlorinated Phthalocyanine |
| Light Green | Titanium Dioxide, Arylamide Yellow, Copper |
| | Phthalocyanine, Arylamide Yellow |
| Light Green | Arylide Yellow, Phthalo Green, Zinc White |
| Light Green | Chlorinated Copper Phthalocyanine, Arylamide |
| | Yellow |
| Light Green | Monoazo Pigment, Polychloro Copper |
| | Phthalocyanine |
| Light Green | Monoazo Pigment, Polychloro Copper |
| | Phthalocyanine |
| Light Green | Zinc Sulfide/Barium Sulfate, Monoazo Yellow, |
| | Phthalocyanine Green |
| Light Green | Chlorinated Copper Phthalocyanine, Arylamide |
| | Yellow |
| Light Green | Monoazo Yellow, Phthalocyanine Blue |
| Light Green | Phthalo Green, Monoazo Yellow |

In addition, fluorescent color brighteners can be added to enhance the optical clarity and optical pick-up recognition of the contrasting color scheme. An example of the fluorescent brightener or color enhancer is: Calcofluor M2R described as a Tinopal UNPA-GX, supplied by Sigma-Aldrich with a preferred loading level of 0.1 to 2.0% by weight. Calcofluor Structure is:

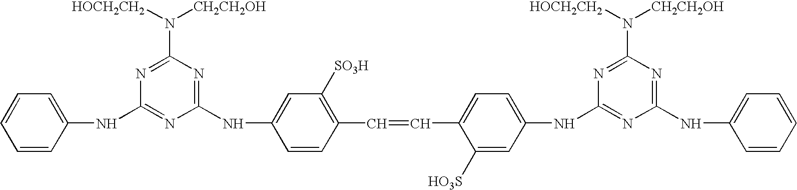

Preferred loading levels range from 5 to 50 percent by weight for each of the dark and light fillers and can be varied by the practitioner depending on the color configuraton of the film. The higher loading range typically would be used for higher levels of UV or light shielding required for some photosensitive devices.

The two-layer film is prepared by laminating together individually coated light and dark, or differently colored, films. The films are first cast onto release liners, and when laminated together the release liners from the two component films end up on the outer sides of the laminated film. The total film thickness is in the range of 25-100 μm. The ratio of dark layer to light layer preferably will be in the range of 4:1 to 1:4.

The two layers may comprise the same or different base resin compositions. One advantage in making the layers from different resins is the capability to make one layer pressure sensitive; the pressure sensitive layer will be tacky and attach easily to the silicon wafer at room temperature. If different resin systems are used, the curing profile will be chosen to meet the time, temperature, and pressure requirements of the resin requiring the longer time, higher temperature, and higher pressure for curing.

Preferred resins for making the films are epoxy resins. A suitable epoxy resin is a glycidyl ether, either used separately or in combination with other types of epoxy resins. Preferred glycidyl ether epoxies are those based on bisphenol A (commercially available from Resolution Technology (e.g. EPON 828)). Another preferred epoxy resin is the diglycidyl ether of bisphenol F, prepared by reacting bisphenol with epichlorohydrin, followed by dehydrochlorination. Bisphenol-F epoxy resins are available commercially from CVC Specialty Chemicals of Maple Shade, N.J., under the designation 8230E, and from Resolution Performance Products LLC under the designation RSL1739. A blend of bisphenol-A and bisphenol-F is available from Nippon Chemical Company under the designation ZX-1059.

Other suitable epoxy resins include polyglycidyl ethers of phenol- or cresol novolacs, prepared by the reaction with epichlorohydrin, followed by dehydrochlorination. A preferred epoxy novolac resin is EPN 1138 from Vantico. Additional suitable epoxy resins are biphenyl epoxy resin, made by reaction of biphenyl resin with epichlorohydrin; epoxy resins based on dicyclo-pentadiene; epoxy resins based on naphthalene; epoxy functional butadiene/acrylonitrile copolymers; epoxy functional polydimethyl siloxane; as well as mixtures of the above.

Cycloaliphatic epoxy resins (i.e. epoxy resins which do not contain glycidyl ether functionality) may also be used. Suitable examples include 3,4-epoxycyclohexylmethyl-3,4-epoxycyclohexane carboxylate, which contains two epoxide groups that are part of the ring structures and an ester linkage; vinylcyclohexene dioxide, which contains two epoxide groups and one of which is part of the ring structure; 3,4-epoxy-6-methyl cyclohexyl methyl-3,4-epoxycyclohexane carboxylate; and dicyclopentadiene dioxide.

Other suitable resins for making non-pressure sensitive layers include compounds with the following structures:

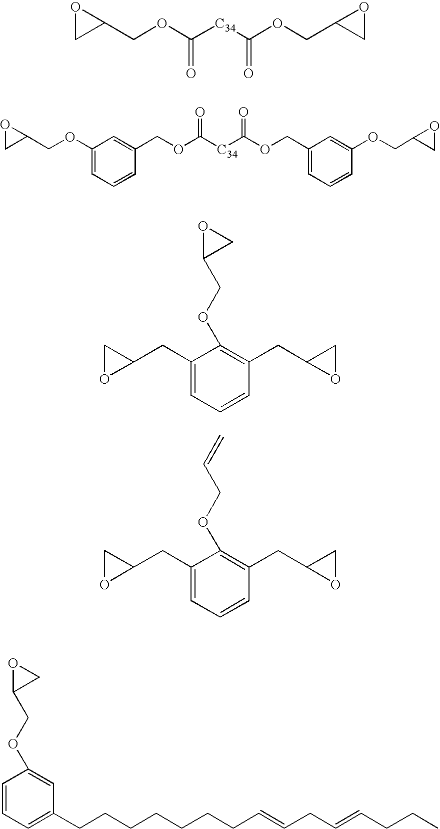

Pressure sensitivity may be imparted by adding components that are liquids at room temperature, but are non-tacky after cure. Suitable materials for this purpose are well known and used in the art, and include the following: thermally curable acrylic resins (such as those available from Sartomer), maleimides (such as those available from Vantico or National Starch and Chemical Company), vinyl compounds (such as vinyl ethers and vinyl silanes available from Aldrich), epoxy compounds (including monofunctional and multifunctional glycidyl ethers of Bisphenol-A or Bisphenol-F aliphatic and cycloaliphatic epoxies available from Vantico, Resolution Technology and others).

Thermoplastic resins may also be used to formulate the films, and if used typically will be used in the range of 20% to 40% by weight of the total film formulation. Suitable resins include, but are not limited to, phenoxy resins, polysulfones, polyethersulfones, polyvinylacetals, polyamides, polyimides, and polyetherimides.

The chosen resin, typically formulated in a solvent based system, is loaded with the colored/pigmented filler and coated horizontally in a mono-layer format on a release coated liner such as that purchased from Loperex as product# 10224-A10/000. The solvent is removed from the coated film in any effective drying operation known to those skilled in the art of film manufacture. One such operation is that conducted in a four stage combination Infrared and convection drier, with the settings dependent on the solvent system used. Exemplary settings are a speed of three feet (approximately one meter) per minute with the temperature stages ramping up from 125° C. in the first stage to 145° C. in the second, 175° C. in the third, and 180° C. in the fourth and final stage. After the film is dried, a second release liner is laminated to the surface of the film by squeezing the film through a heated roller, for example, at 135° C.

A second film with a different colored filler is prepared in the same way. The two finished films are combined in a lamination process to form a single two-layer film. One of the release liners is removed from each of the films and the films contacted together so that the release liners are on the outer sides of the combined films. The combined films are passed through the heated roller (with the release liners in contact with the roller). Exemplary lamination conditions are 77° C., 1.3 meter per minute (approximately 4 feet per minute) and pressure of 1.76 Kg/cm² (approximately 25 psi).

The film can be converted to a series of different formats; for example, it can be slit down to form reels or rolls, or punched into shapes such as squares or circles for individual consumption or for mounting onto a continuous roll.

The two-layer film is laminated onto the silicon wafer (after first removing one release liner) using automated laminating equipment. Typical conditions of heat and pressure are 80° to 100° C. and 0.35 to 2.1 Kg force/cm² (5 to 30 psi) at approximately 0.7 meter per minute. It will be understood that these are exemplary conditions, and actual conditions will vary with the resin composition. Such conditions can be obtained with a minimum of experimentation. Any film remnants at the edge of the wafer are trimmed away and the film is then cured on the wafer in an oven. Exemplary conditions are a 30 minute ramp from 25° C. to 90° C., hold for 30 minutes at 90° C., 30 minute ramp from 90° C. to 150° C., hold for 90 minutes at 150° C. Other exemplary conditions are a 60 minute ramp from room temperature to 165° C., hold for one hour at 165° C. Actual curing conditions will vary with the resin system chosen.

At this point, the two-layer tape is marked for identification as desired by a laser. Such processes are known and used in the art.

Example: The following adhesive formulation was prepared in two batches:

| | |
|---|---|
| Toluene | 0.1 to 15% by weight |
| Ethanol | 0.1 to 15% by weight |
| Polyvinyl acetal | 1 to 35% by weight |
| Phenol novolac | 10 to 25% by weight |
| Epoxidized phenol novolac | 5 to 15% by weight |
| Bisphenol F diglycidyl ether | 5 to 15% by weight |
| Carbonic Acid Amine Catalyst 0276 | 0.1 to 5% by weight |
| Epoxy silane | 0.1 to 25% by weight |
| Methyl Ethyl Ketone | 0.1 to 15% by weight. |

One batch was loaded with titanium dioxide to 35% by weight, and the second batch was loaded with carbon black to 35% by weight. The batch containing titanium dioxide was coated onto a release liner to a dry thickness of 0.5 mil; the batch containing the carbon black was coated onto a release liner to a dry thickness of 1 ml. The coating and drying were performed as described in this specification. The two films were laminated together and mounted onto a silicon wafer as described in this specification and marked with a green laser at 95% power, with a beam speed of 100 mm/sec, and a pulse rate of 8 Khz.

What is claimed:

1. A two layer adhesive film, 25 μm to 100 μm thick, in which one layer is light colored and the second layer is dark colored, or in which the layers are of contrasting colors.

2. The film according to claim 1 in which the ratio of the thickness of the layers ranges from 1:4 to 4:1.

3. The adhesive film according to claim 1 or 2 in which the light colored layer contains titanium dioxide and the dark colored layer contains carbon black.
